(19) United States
(12) Patent Application Publication
(10) Pub. No.: US 2023/0307280 A1
(43) Pub. Date: Sep. 28, 2023

(54) APPARATUS AND METHOD FOR MANUFACTURING DISPLAY DEVICE

(71) Applicant: Samsung Display Co., LTD., Yongin-si (KR)

(72) Inventor: Joo Nyung JANG, Seoul (KR)

(73) Assignee: Samsung Display Co., LTD., Yongin-si (KR)

(21) Appl. No.: 17/987,378

(22) Filed: Nov. 15, 2022

(30) Foreign Application Priority Data
Feb. 7, 2022 (KR) 10-2022-0015639

(51) Int. Cl. H01L 21/68; H01L 33/00

(52) U.S. Cl. CPC H01L 21/68; H01L 33/005; H01L 25/0753

(57) ABSTRACT

An apparatus for manufacturing a display device includes a panel cell disposed on a stage and comprising a first alignment line and a second alignment line extending in at least one direction, an electric field applying part that supplies a first alignment signal and a second alignment signal to the panel cell, and a light emitting element aligned between the first and second alignment lines. The electric field applying part supplies the first and second alignment signals having a potential difference to the first and second alignment lines, respectively, during a first period, and supplies the first and second alignment signals having a same potential to the first and second alignment lines, respectively, during a second period after the first period.

### CROSS-REFERENCE TO RELATED APPLICATION

This application claims priority to and benefits of Korean Patent Application No. 10-2022-0015639 under 35 U.S.C. §119, filed in the Korean Intellectual Property Office on Feb. 7, 2022, the entire contents of which are incorporated herein by reference.

### BACKGROUND

### 1. Technical Field

The disclosure relates to an apparatus and method for manufacturing a display device, which is capable of improving luminous efficiency of the display device by improving alignment and deflection efficiency of a light emitting element.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as a light emitting display panel or a liquid crystal display panel. Among them, the light emitting display panel may display an image by emitting light using a light emitting element. When a light emitting diode (LED) is used as the light emitting element, an organic light emitting diode (OLED) using an organic material as a fluorescent material, an inorganic light emitting diode using an inorganic material as a fluorescent material, or the like may be used as the light emitting element. An apparatus for manufacturing a display device may align an inorganic light emitting diode on the display device using an electric field signal.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide an apparatus capable of improving luminous efficiency of a display device by improving alignment and deflection efficiency of a light emitting element.

Embodiments also provide a method for manufacturing a display device, which is capable of improving luminous efficiency of the display device by improving alignment and deflection efficiency of a light emitting element.

However, embodiments of the disclosure are not limited to the those set forth herein. The above and other embodiments will become more apparent to one of ordinary skill in the art to which the disclosure pertains by referencing the detailed description of the disclosure given below.

According to an embodiment of the disclosure, an apparatus for manufacturing a display device comprises a panel cell disposed on a stage and comprising a first alignment line and a second alignment line extending in at least one direction, an electric field applying part that supplies a first alignment signal and a second alignment signal to the panel cell, and a light emitting element aligned between the first and second alignment lines. The electric field applying part supplies the first and second alignment signals having a potential difference to the first and second alignment lines respectively during a first period, and supplies the first and second alignment signals having a same potential to the first and second alignment lines respectively during a second period after the first period.

The first alignment signal of the first period may be an alternating current (AC) signal swinging with a frequency, and the second alignment signal of the first period may be a direct current (DC) signal having a voltage.

The first and second alignment signals of the first period may be AC signals swinging with a frequency, and the first and second alignment signals may have different phases from each other.

The first and second alignment signals of the second period may be AC signals swinging with a same frequency and phase.

Each of the first and second alignment signals of the second period may be one of a sine wave, a square wave, a triangle wave, a pulse wave, a sawtooth wave, a sawtooth composite wave, and a reverse sawtooth composite wave.

A force by an induced dipole may be smaller than a force by a permanent dipole adjacent to the first and second alignment lines during the second period, and the light emitting element may stand vertically by an electric field adjacent to the first and second alignment lines during the second period.

The electric field applying part may supply the first and second alignment signals having a potential difference to the first and second alignment lines respectively during a third period after the second period.

The first alignment signal of the third period may be an AC signal swinging with a frequency, and the second alignment signal of the third period may be a DC signal having a voltage.

The first and second alignment signals of the third period may be AC signals swinging with a frequency, and the first and second alignment signals may have different phases from each other.

Each of the first and second alignment signals of the third period may be one of a sine wave, a square wave, a triangle wave, a pulse wave, a sawtooth wave, a sawtooth composite wave, and a reverse sawtooth composite wave.

The apparatus for manufacturing a display device may further comprise a voltage output part that generates and outputs the first and second alignment signals, an amplifier that amplifies the first and second alignment signals and supplies the amplified first and second alignment signals to the electric field applying part, a controller that supplies a control signal for determining waveforms of the first and second alignment signals to the voltage output part, an emission driver that receives an emission timing signal from the controller and outputs an emission driving signal, and a light irradiation part that receives the emission driving signal from the emission driver and irradiates light to the panel cell.

According to an embodiment of the disclosure, a method for manufacturing a display device comprises providing a panel cell comprising a first alignment line and a second alignment line extending in at least one direction, supplying a first alignment signal and a second alignment signal having a potential difference to the first and second alignment lines respectively during a first period, supplying a first alignment signal and a second alignment signal having a same potential to the first and second alignment lines respectively during a second period after the first period, and supplying a first alignment signal and a second alignment signal having a potential difference to the first and second alignment lines respectively during a third period after the second period.

The first alignment signal of the first period may be an AC signal swinging with a frequency, and the second alignment signal of the first period may be a DC signal having a voltage.

The first and second alignment signals of the first period may be AC signals swinging with a frequency, and the first and second alignment signals may have different phases from each other.

The first and second alignment signals of the second period may be AC signals swinging with a same frequency and phase.

Each of the first and second alignment signals of the second period may be one of a sine wave, a square wave, a triangle wave, a pulse wave, a sawtooth wave, a sawtooth composite wave, and a reverse sawtooth composite wave.

The supplying of the first and second alignment signals during the second period may comprise forming an electric field adjacent to the first and second alignment lines to vertically erect a light emitting element aligned between the first and second alignment lines.

The first alignment signal of the third period may be an AC signal swinging with a frequency, and the second alignment signal of the third period may be a DC signal having a voltage.

The first and second alignment signals of the third period may be AC signals swinging with a frequency, and the first and second alignment signals may have different phases from each other.

Each of the first and second alignment signals of the third period may be one of a sine wave, a square wave, a triangle wave, a pulse wave, a sawtooth wave, a sawtooth composite wave, and a reverse sawtooth composite wave.

In the apparatus and method for manufacturing a display device according to embodiments, first and second alignment signals having a potential difference may be supplied during a first period, the first and second alignment signals having the same potential may be supplied during a second period, and the first and second alignment signals having a potential difference may be supplied during a third period to improve alignment and deflection efficiency of the light emitting element. Thus, luminous efficiency of the display device may be improved.

However, the effects of the present disclosure are not limited to the aforementioned effects, and various other effects are included in the present disclosure.

### BRIEF DESCRIPTION OF THE DRAWINGS

An additional appreciation according to the embodiments of the disclosure will become more apparent by describing in detail embodiments thereof with reference to the accompanying drawings, wherein:

FIG. 1 is a schematic perspective view showing a display device according to an embodiment;

FIG. 2 is a schematic plan view illustrating a display device according to an embodiment;

FIG. 3 is a schematic plan view illustrating a pixel of a display device according to an embodiment;

FIG. 4 is a schematic perspective view illustrating a light emitting element of a display device according to an embodiment;

FIG. 5 is a schematic cross-sectional view taken along line I-I′ of FIG. 3;

FIG. 6 is a schematic plan view illustrating a mother substrate according to an embodiment;

FIG. 7 is a schematic plan view illustrating a panel cell of FIG. 6;

FIG. 8 is a schematic cross-sectional view illustrating an apparatus for manufacturing a display device according to an embodiment;

FIG. 9 is a schematic block diagram illustrating an apparatus for manufacturing a display device according to an embodiment;

FIG. 10 is a schematic plan view illustrating first and second vertical alignment lines and light emitting elements in a first period in a manufacturing process of a display device according to an embodiment;

FIG. 11 is a schematic waveform diagram illustrating first and second alignment signals in the manufacturing process of the display device of FIG. 10 according to an embodiment;

FIG. 12 is a schematic waveform diagram illustrating first and second alignment signals in the manufacturing process of the display device of FIG. 10 according to an embodiment;

FIG. 13 is a schematic cross-sectional view taken along lines II-II′ and III-III′ of FIG. 10;

FIG. 14 is a schematic plan view illustrating first and second vertical alignment lines and light emitting elements in a second period in a manufacturing process of a display device according to an embodiment;

FIG. 15 is a schematic waveform diagram illustrating first and second alignment signals in the manufacturing process of the display device of FIG. 14;

FIG. 16 is a schematic cross-sectional view taken along lines IV-IV′ and V-V′ of FIG. 14;

FIG. 17 is a schematic plan view illustrating first and second vertical alignment lines and light emitting elements in a third period in a manufacturing process of a display device according to an embodiment;

FIG. 18 is a schematic waveform diagram illustrating first and second alignment signals in the manufacturing process of the display device of FIG. 17 according to an embodiment;

FIG. 19 is a schematic waveform diagram illustrating first and second alignment signals in the manufacturing process of the display device of FIG. 17 according to an embodiment;

FIG. 20 is a schematic cross-sectional view taken along lines VI-VI′ and VII′-VII′ of FIG. 17; and

FIG. 21 is a schematic flowchart illustrating a manufacturing process of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. For example, well-known structures and devices are shown in block diagram form in order to avoid unnecessarily obscuring various embodiments. Here, various embodiments may be different, but do not have to be exclusive. For example, specific shapes, configurations, and characteristics of an embodiment may be used or implemented in another embodiment.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z- axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or overly formal sense, unless clearly so defined herein.

Hereinafter, detailed embodiments of the present disclosure will be described with reference to the accompanying drawings.

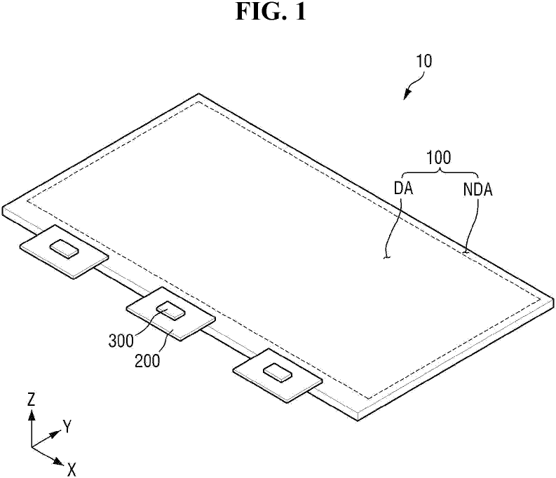

FIG. 1 is a schematic perspective view showing a display device according to an embodiment.

Referring to FIG. 1, a display device 10 may display a moving image or a still image. For example, the display device 10 may be applied to portable electronic devices such as a mobile phone, a smartphone, a tablet personal computer (PC), a mobile communication terminal, an electronic organizer, an electronic book, a portable multimedia player (PMP), a navigation system, an ultra mobile PC (UMPC) or the like. In an embodiment, the display device 10 may be applied as a display part of a television, a laptop, a monitor, a billboard, or an Internet-of-Things (IoT) device. In other embodiments, the display device 10 may be applied to wearable devices such as a smart watch, a watch phone, a glasses type display, or a head mounted display (HMD). In other embodiments, the display device 10 may be applied to a dashboard of a vehicle, a center fascia of a vehicle, a center information display (CID) disposed on a dashboard of a vehicle, a room mirror display in place of side mirrors of a vehicle, or a display disposed on a rear surface of a front seat for rear seat entertainment of a vehicle.

The display device 10 may have a planar shape similar to a quadrilateral shape. For example, the display device 10 may have a shape similar to a quadrilateral shape, in a plan view, having long sides in a first direction (or in an X-axis direction) and short sides in a second direction (or in a Y-axis direction). A corner where the long side in the first direction (or in the X-axis direction) and the short side in the second direction (or in the Y-axis direction) meet may be rounded to have a curvature (e.g., a predetermined curvature or selectable curvature) or may be right-angled. The planar shape of the display device 10 is not limited to the quadrilateral shape, and may be formed in a shape similar to another polygonal shape, a circular shape, or elliptical shape.

The display device 10 may include a display panel 100, a circuit board 200, and a display driver 300. The display panel 100 may include a display area DA and a non-display area NDA.

The display area DA may include pixels displaying an image. The display area DA may emit light from emission areas or opening areas. The display panel 100 may include a pixel circuit including switching elements, a pixel defining layer defining an emission area or an opening area, and a self-light emitting element. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be adjacent to (e.g., disposed around) the display area DA. The non-display area NDA may be defined as an edge area of the display panel 100. The non-display area NDA may include a gate driver supplying gate signals to gate lines, fan-out lines electrically connecting the display driver 300 to the display area DA, and a pad portion electrically connected to the circuit board 200.

The circuit board 200 may be attached to the pad portion of the display panel 100 by using an anisotropic conductive film (ACF). Lead lines of the circuit board 200 may be electrically connected to the pad portion of the display panel 100. The circuit board 200 may be a flexible printed circuit board, a printed circuit board, or a flexible film such as a chip on film.

The display driver 300 may output signals and voltages for driving the display panel 100. The display driver 300 may supply a data voltage to a data line. The display driver 300 may supply a power voltage to a power line and may supply a gate control signal to the gate driver. The display driver 300 may be formed of an integrated circuit (IC) and mounted on the circuit board 200. In other embodiments, the display driver 300 may be mounted on the display panel 100 by a chip on glass (COG) method, a chip on plastic (COP) method, or an ultrasonic bonding method.

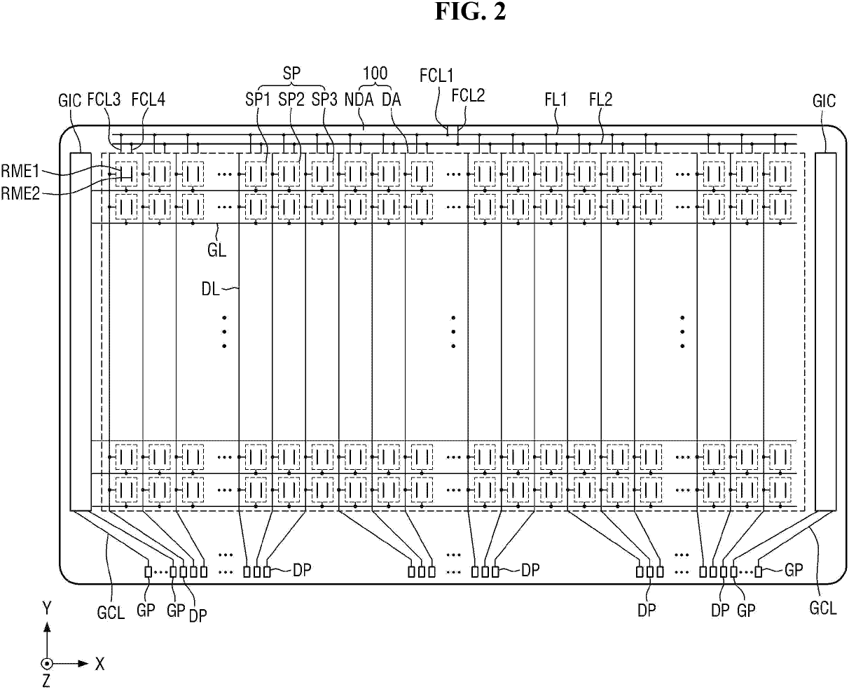

FIG. 2 is a schematic plan view illustrating a display device according to an embodiment.

Referring to FIG. 2, the display panel 100 may include gate lines GL, data lines DL, pixels SP, a gate driver GIC, a gate control line GCL, first and second floating lines FL1 and FL2, first to fourth connection lines FCL1, FCL2, FCL3, and FCL4, a display pad portion DP, and a gate pad portion GP.

The gate lines GL, the data lines DL, and the pixels SP may be disposed in the display area DA of the display panel 100.

The gate lines GL may extend in the first direction (or in the X-axis direction) and may be spaced apart from each other in the second direction (or in the Y-axis direction). The gate lines GL may supply gate signals received from the gate driver GIC to the pixels SP.

The data lines DL may extend in the second direction (or in the Y-axis direction) and may be spaced apart from each other in the first direction (or in the X-axis direction). The data lines DL may be electrically connected to the display driver 300 through the display pad portion DP. The data lines DL may supply the data voltages received from the display driver 300 to the pixels SP.

The pixels SP may include first to third pixels SP1, SP2, and SP3 that emit light of different colors. The pixels SP may include the three pixels (e.g., the first to third pixels SP1, SP2, and SP3), but the number of pixels is not limited thereto. In other embodiments, the pixels SP may include four pixels.

The first to third pixels SP1, SP2, and SP3 may be arranged in the first direction (or in the X-axis direction) and the second direction (or in the Y-axis direction). The first to third pixels SP1, SP2, and SP3 may be arranged in a matrix form. The first to third pixels SP1, SP2, and SP3 may be sequentially arranged in the first direction (or in the X-axis direction). Each of the first to third pixels SP1, SP2, and SP3 may be arranged on a same line in the second direction (or in the Y-axis direction), but is not limited thereto.

Each of the first to third pixels SP1, SP2, and SP3 may include a first electrode RME1 and a second electrode RME2. The first electrode RME1 and the second electrode RME2 may extend in the second direction (or in the Y-axis direction) and may be spaced apart from each other in the first direction (or in the X-axis direction). The first electrode RME1 and the second electrode RME2 in each of the pixels SP may be insulated (e.g., electrically insulated) from each other. For example, the first electrode RME1 of one pixel SP may be spaced apart from the first electrode RME1 of another pixel SP adjacent in the first direction (or in the X-axis direction) or the second direction (or in the Y-axis direction). The second electrode RME2 of one pixel SP may be spaced apart from the second electrode RME2 of another pixel SP adjacent in the first direction (or in the X-axis direction) or the second direction (or in the Y-axis direction).

The light emitting elements may be disposed between the first electrode RME1 and the second electrode RME2. An end of each of the light emitting elements may be electrically connected to the first electrode RME1, and another end thereof may be electrically connected to the second electrode RME2. The light emitting element may emit light by a driving current flowing from the first electrode RME1 to the second electrode RME2.

The gate driver GIC, the gate control line GCL, the first and second floating lines FL1 and FL2, the first to fourth connection lines FCL1, FCL2, FCL3, and FCL4, the display pad portion DP, and the gate pad portion GP may be disposed in the non-display area NDA of the display panel 100.

The gate driver GIC may be electrically connected to the gate pad portion GP through the gate control line GCL. The gate driver GIC may be electrically connected to the circuit board 200 through the gate pad portion GP. The gate driver GIC may generate a gate signal based on the gate control signal received from the circuit board 200 and may sequentially supply the gate signal to the gate lines GL.

The gate driver GIC may be disposed at each of left and right edges of the non-display area NDA, but is not limited thereto. In other embodiments, the gate driver GIC may be disposed at one of the left and the right edges of the non-display area NDA.

The first and second floating lines FL1 and FL2 and the first to fourth connection lines FCL1, FCL2, FCL3, and FCL4 may supply first and second alignment signals to the pixels SP in a manufacturing process of the display device 10. The first and second floating lines FL1 and FL2 and the first to fourth connection lines FCL1, FCL2, FCL3, and FCL4 may be electrically connected to the first electrode RME1 or the second electrode RME2 in an alignment process of the light emitting elements. In case that the light emitting elements are completely aligned, the first and second floating lines FL1 and FL2 and the first to fourth connection lines FCL1, FCL2, FCL3, and FCL4 may be electrically isolated without being electrically connected to the first and second electrodes RME1 and RME2 of each of the first to third pixels SP1, SP2, and SP3, the gate lines GL, or the data lines DL. Accordingly, in case that the manufacturing of the display device 10 is completed, the first and second floating lines FL1 and FL2 and the first to fourth connection lines FCL1, FCL2, FCL3, and FCL4 may not receive a separate voltage. In other embodiments, the first and second floating lines FL1 and FL2 and the first to fourth connection lines FCL1, FCL2, FCL3, and FCL4 may receive a ground voltage or a DC voltage having a level (e.g., a predetermined level or selectable level) to prevent static electricity.

The first and second floating lines FL1 and FL2 may extend in the first direction (or in the X-axis direction) and may be spaced apart from each other in the second direction (or in the Y-axis direction). The first and second floating lines FL1 and FL2 may be disposed at an upper edge of the non-display area NDA.

The first floating line FL1 may be electrically connected between the first and third connection lines FCL1 and FCL3. Each of the first and third connection lines FCL1 and FCL3 may extend in the second direction (or in the Y-axis direction). The first connection line FCL1 may extend from the first floating line FL1 in an upward direction of the display panel 100. The third connection line FCL3 may extend from the first floating line FL1 toward the display area DA. The first connection line FCL1 may be electrically connected to a first alignment pad of a mother substrate.

The second floating line FL2 may be electrically connected between the second and fourth connection lines FCL2 and FCL4. Each of the second and fourth connection lines FCL2 and FCL4 may extend in the second direction (or in the Y-axis direction). The second connection line FCL2 may extend from the second floating line FL2 in the upward direction of the display panel 100. The fourth connection line FCL4 may extend from the second floating line FL2 toward the display area DA. The second connection line FCL2 may be electrically connected to a second alignment pad of the mother substrate.

The display pad portion DP and the gate pad portion GP may be disposed at a lower edge of the non-display area NDA. The circuit boards 200 disposed on left and right sides of the lower edge of the non-display area NDA may be electrically connected to the display pad portion DP and the gate pad portion GP. The circuit board 200 disposed in the center of the lower edge of the non-display area NDA may be electrically connected to the display pad portion DP. The gate pad portion GP electrically connected to the circuit board 200 disposed on the left side of the lower edge of the non-display area NDA may be disposed to a left side of the display pad portion DP. The gate pad portion GP electrically connected to the circuit board 200 disposed on the right side of the lower edge of the non-display area NDA may be disposed to a right side of the display pad portion DP.

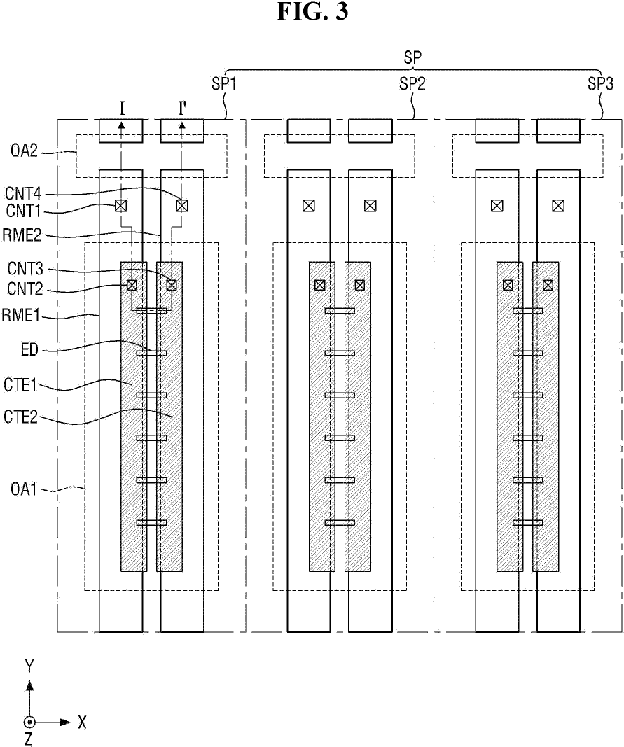

FIG. 3 is a schematic plan view illustrating a pixel of a display device according to an embodiment.

Referring to FIG. 3, the pixels SP may include the first to third pixels SP1, SP2, and SP3 that emit light of different colors. The pixels SP may include three pixels, but the number of pixels included in the pixels SP is not limited thereto. In other embodiments, the pixels SP may include four pixels. Each of the pixels SP may be defined as an area of the smallest part that outputs light.

The first pixel SP1 may emit light of a first color. The second pixel SP2 may emit light of a second color. The third pixel SP3 may emit light of a third color. For example, the first color light may be red light having a peak wavelength in a range of about 610 nm to about 650 nm. The second color light may be green light having a peak wavelength in a range of about 510 nm to about 550 nm. The third color light may be blue light having a peak wavelength in a range of about 440 nm to about 480 nm. However, the disclosure is not limited thereto.

Each of the first to third pixels SP1, SP2, and SP3 may include the first electrode RME1, the second electrode RME2, a first contact electrode CTE1, a second contact electrode CTE2, and a light emitting element ED.

The first electrode RME1 may be a pixel electrode separated for each of the first to third pixels SP1, SP2, and SP3, and the second electrode RME2 may be a common electrode separated for each of the first to third pixels SP1, SP2, and SP3. For example, the first electrode RME1 may be an anode electrode electrically connected to an end of the light emitting element ED, and the second electrode RME2 may be a cathode electrode electrically connected to another end of the light emitting element ED. The first and second electrodes RME1 and RME2 may extend in the second direction (or in the Y-axis direction). The first and second electrodes RME1 and RME2 may be spaced apart from each other in the first direction (or in the X-axis direction) and may be electrically insulated from each other.

The first electrode RME1 may be electrically connected to the pixel circuit through a first contact hole CNT1. The first electrode RME1 may be electrically connected to a source electrode or a drain electrode of a thin film transistor through the first contact hole CNT1. The second electrode RME2 may be electrically connected to the power line through a fourth contact hole CNT4.

Each of the first to third pixels SP1, SP2, and SP3 may include a first electrode RME1 (e.g., one first electrode RME1) and a second electrode RME2 (e.g., one second electrode RME2), but is not limited thereto. In an embodiment, each of the first to third pixels SP1, SP2, and SP3 may include two or more first electrodes RME1 or second electrodes RME2. In other embodiments, each of the first to third pixels SP1, SP2, and SP3 may include two first electrodes RME1 and a second electrode (e.g., one second electrode RME2).

The first contact electrode CTE1 and the second contact electrode CTE2 may extend in the second direction (or in the Y-axis direction). The first and second contact electrodes CTE1 and CTE2 may be spaced apart from each other in the first direction (or in the X-axis direction) and may be electrically insulated from each other. A length of the first contact electrode CTE1 in the second direction (or in the Y-axis direction) may be smaller than a length of the first electrode RME1 in the second direction (or in the Y-axis direction). A length of the second contact electrode CTE2 in the second direction (or in the Y-axis direction) may be smaller than a length of the second electrode RME2 in the second direction (or in the Y-axis direction). A length of the first contact electrode CTE1 in the first direction (or in the X-axis direction) may be smaller than a length of the first electrode RME1 in the first direction (or in the X-axis direction). A length of the second contact electrode CTE2 in the first direction (or in the X-axis direction) may be smaller than a length of the second electrode RME2 in the first direction (or in the X-axis direction).

The first contact electrode CTE1 may overlap the first electrode RME1 in a third direction (or in the Z-axis direction). The first contact electrode CTE1 may be electrically connected to the first electrode RME1 through a second contact hole CNT2. The second contact electrode CTE2 may overlap the second electrode RME2 in the third direction (or in the Z-axis direction). The second contact electrode CTE2 may be electrically connected to the second electrode RME2 through a third contact hole CNT3.

The first contact electrode CTE1 may be in contact with an end of the light emitting element ED, and the second contact electrode CTE2 may be in contact with the another end of the light emitting element ED. Accordingly, the end of the light emitting element ED may be electrically connected to the first electrode RME1 through the first contact electrode CTE1, and the another end of the light emitting element ED may be electrically connected to the second electrode RME2 through the second contact electrode CTE2.

The light emitting elements ED may be spaced apart from each other. The light emitting elements ED may extend in the first direction (or in the X-axis direction) and may be spaced apart from each other in the second direction (or in the Y-axis direction). The light emitting elements ED may be disposed in a first opening area OA1 defined by a bank or the pixel defining layer. One end of each of the light emitting elements ED may be in contact with (or may contact) the first contact electrode CTE1, and the another end of each of the light emitting elements ED may be in contact with the second contact electrode CTE2. One end of each of the light emitting elements ED may overlap the first electrode RME1 in the third direction (or in the Z-axis direction), and the another end thereof may overlap the second electrode RME2 in the third direction (or in the Z-axis direction).

The light emitting element ED may have a shape of a rod, a wire, a tube, or the like. For example, the light emitting element ED may have a cylindrical shape or a rod shape. In an embodiment, the light emitting element ED may have a polyhedral shape such as a regular cube and a rectangular parallelepiped, or a polygonal prism shape such as a hexagonal prism. In other embodiments, the light emitting element ED may have a shape such as a circular truncated cone, extending in a direction and having an outer surface partially inclined. The light emitting element ED may have a micro-meter or nano-meter size, and may be an inorganic light emitting diode including an inorganic material. The light emitting element ED may be aligned between the first electrode RME1 and the second electrode RME2 facing each other by an electric field formed in a direction between the first electrode RME1 and the second electrode RME2.

The bank or the pixel defining layer may define the first opening area OA1 and a second opening area OA2 of the first to third pixels SP1, SP2, and SP3. The first opening area OA1 may be an emission area in which the light emitting elements ED are disposed. The second opening area OA2 may be a separation area that separates the first and second electrodes RME1 and RME2 of the pixels SP adjacent in the second direction (or in the Y-axis direction). For example, the first electrode RME1 of a pixel SP of the pixels SP may be spaced apart from the first electrode RME1 of another pixel SP of the pixels SP adjacent in the second direction (or in the Y-axis direction) by the second opening area OA2, and the second electrode RME2 of the pixel SP of the pixels SP may be spaced apart from the second electrode RME2 of the another pixel SP of the pixels SP adjacent in the second direction (or in the Y-axis direction) by the second opening area OA2. The first electrodes RME1 of the pixels SP (e.g., adjacent ones of the first electrodes RME1 of adjacent ones of the pixels SP) adjacent in the second direction (or in the Y-axis direction) may be spaced apart from each other by the second opening area OA2. The second electrodes RME2 of the pixels SP (e.g., adjacent ones of the second electrodes RME2 of the adjacent ones of the pixels SP) adjacent in the second direction (or in the Y-axis direction) may be spaced apart from each other.

In other embodiments, the first opening area OA1 and the second opening area OA2 may be formed as an opening area. For example, the first opening area OA1 and the second opening area OA2 may be integral with each other.

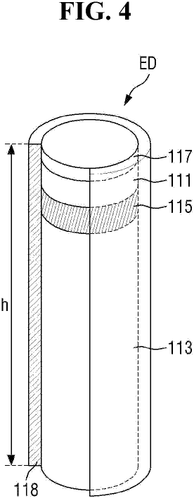

FIG. 4 is a schematic perspective view illustrating a light emitting element of a display device according to an embodiment.

Referring to FIGS. 3 and 4, the light emitting element ED may include a first semiconductor portion 111, a second semiconductor portion 113, an active layer 115, an electrode layer 117, and an insulating film 118.

The first semiconductor portion 111 may be disposed on the active layer 115. The first semiconductor portion 111 may be electrically connected to the first electrode RME1 through the electrode layer 117 and the first contact electrode CTE1. For example, when the light emitting element ED emits blue or green light, the first semiconductor portion 111 may include a semiconductor material having a chemical formula of AlₓGa_{y}In_{1-x-y}N (0≤x≤1, 0≤y≤1, 0≤x+y≤1). For example, the first semiconductor portion 111 may include at least one semiconductor material of p-type doped with at least one of AlGaInN, GaN, AlGaN, InGaN, A1N, and InN. The first semiconductor portion 111 may be doped with p-type dopants including at least one of Mg, Zn, Ca, Se, and Ba. The first semiconductor portion 111 may be p-type Mg-doped p-GaN. A length of the first semiconductor portion 111 may have a range of about 0.05 µm to about 0.10 µm, but is not limited thereto.

The second semiconductor portion 113 may be electrically connected to the second electrode RME2 through the second contact electrode CTE2. The second semiconductor portion 113 may be an n-type semiconductor. For example, when the light emitting element ED emits blue light, the second semiconductor portion 113 may include a semiconductor material having a chemical formula of AlₓGa_{y}In_{1-x-y}N (0≤x≤1, 0≤y≤1, 0≤x+y≤1). The second semiconductor portion 113 may include at least one semiconductor material of n-type doped with at least one of AlGaInN, GaN, AlGaN, InGaN, A1N, and InN. The second semiconductor portion 113 may be doped with n-type dopants including at least one of Si, Ge, and Sn. The second semiconductor portion 113 may be n-type Si-doped n-GaN. A length of the second semiconductor portion 113 may have a range of about 1.5 µm to about 5 µm, but is not limited thereto.

Each of the first and second semiconductor portions 111 and 113 may be formed as a single layer, but the disclosure is not limited thereto. For example, each of the first and second semiconductor portions 111 and 113 may further include a clad layer or a tensile strain barrier reducing (TSBR) layer to have a multilayer structure.

The active layer 115 may be disposed between the first and second semiconductor portions 111 and 113. The active layer 115 may include a material having a single or multiple quantum well structure. When the active layer 115 includes a material having a multiple quantum well structure, quantum layers and well layers may be alternately stacked one another. Electron-hole pairs may be coupled according to an electric signal applied through the first and second semiconductor portions 111 and 113, and the active layer 115 may emit light. For example, when the active layer 115 includes a material such as AlGaN, AlGaInN or the like, the active layer 115 may emit the blue light. When the active layer 115 has the multiple quantum well structure in which quantum layers and well layers are alternately stacked one another, the quantum layer may include a material such as AlGaN or AlGaInN, and the well layer may include a material such as GaN or AlInN. The active layer 115 may include the quantum layer made of AlGaInN and the well layer made of AlInN and emit the blue light.

In other embodiments, the active layer 115 may have a structure in which semiconductor materials having large band gap energy and semiconductor materials having small band gap energy are alternately stacked one another. The active layer 115 may include Group III to V semiconductor materials according to the wavelength band of the emitted light. The light emitted by the active layer 115 is not limited to the blue light, and the active layer 115 may emit red or green light in some cases. A length of the active layer 115 may have a range of about 0.05 µm to about 0.10 µm, but is not limited thereto.

Light emitted from the active layer 115 may be emitted in a longitudinal direction of the light emitting element ED. The light may also be emitted from both side surfaces of the light emitting element ED. The directionality of the light emitted from the active layer 115 may not be limited. For example, the active layer 115 may emit the light in various directions.

The electrode layer 117 may be an ohmic contact electrode. In an embodiment, the electrode layer 117 may be a Schottky contact electrode. The light emitting element ED may include at least one electrode layer 117. The electrode layer 117 may reduce resistance between the light emitting element ED and the first contact electrode CTE1 in case that the light emitting element ED is connected to the first contact electrode CTE1. The electrode layer 117 may contain a conductive metal or metal oxide. For example, the electrode layer 117 may include at least one of aluminum (Al), titanium (Ti), indium (In), gold (Au), silver (Ag), indium tin oxide (ITO), indium zinc oxide (IZO), and indium tin zinc oxide (ITZO). The electrode layer 117 may include an n-type or p-type doped semiconductor material.

The insulating film 118 may be adjacent to surfaces (e.g., surround the outer surfaces) of the first and second semiconductor portions 111 and 113, the active layer 115, and the electrode layer 117. The insulating film 118 may protect the light emitting element ED. For example, the insulating film 118 may surround the side surface of the light emitting element ED, and may expose the both ends of the light emitting element ED in the longitudinal direction.

The insulating film 118 may include materials having insulating properties. For example, the insulating film 118 may include at least one of silicon oxide (SiOₓ), silicon nitride (SiNₓ), silicon oxynitride (SiOₓN_{y}), aluminum nitride (A1N), and aluminum oxide (A₂O₃). However, the disclosure is not limited thereto. Accordingly, the insulating film 118 may prevent an electrical short circuit that may occur when the active layer 115 is in direct contact with the electrode through which the electrical signal is transmitted to the light emitting element ED. The insulating film 118 may protect the outer surface of the light emitting element ED including the active layer 115. Thus, a decrease in luminous efficiency of the light emitting element ED may be prevented.

An outer surface of the insulating film 118 may be surface-treated. When manufacturing the display panel 100, the light emitting elements ED may be sprayed and aligned on the electrodes in a state of being dispersed in ink. The surface of the insulating film 118 may be subjected to a hydrophobic or hydrophilic treatment. Thus, the light emitting element ED may maintain a dispersed state without being aggregated with adjacent light emitting elements ED in the ink.

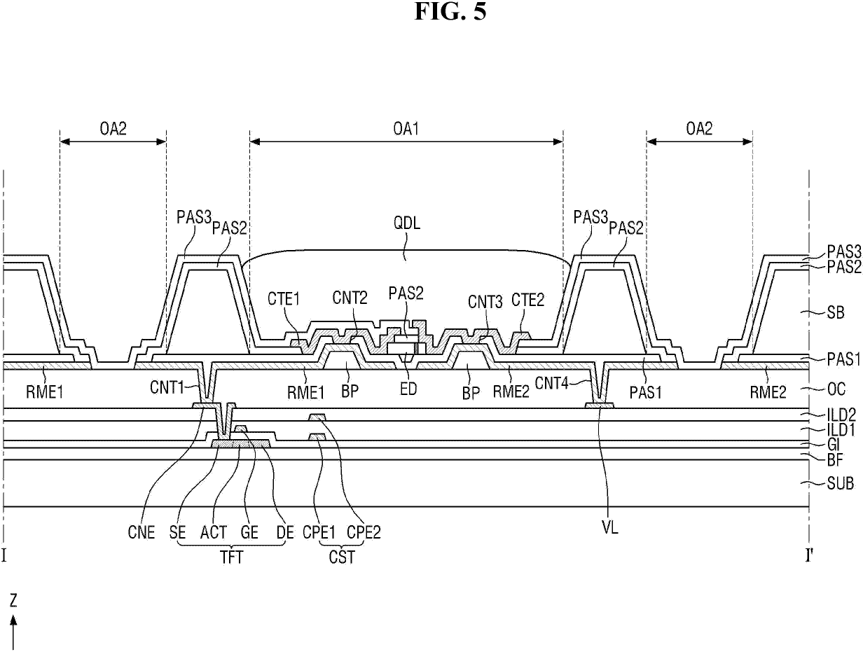

FIG. 5 is a schematic cross-sectional view taken along line I-I′ of FIG. 3.

Referring to FIG. 5, the display panel 100 may include a substrate SUB, a buffer layer BF, a thin film transistor TFT, a gate insulating layer GI, a storage capacitor CST, first and second interlayer insulating layers ILD1 and ILD2, a connection electrode CNE, a voltage line VL, a planarization layer OC, a bank pattern BP, the first electrode RME1, the second electrode RME2, a first insulating layer PAS1, a bank SB, the light emitting element ED, a second insulating layer PAS2, the first contact electrode CTE1, the second contact electrode CTE2, a third insulating layer PAS3, and a wavelength conversion layer QDL.

The substrate SUB may be a base substrate or a base member. The substrate SUB may support the display panel 100. The substrate SUB may be a flexible substrate which may be bent, folded, or rolled. For example, the substrate SUB may include a polymer resin such as polyimide (PI), but is not limited thereto. In other embodiments, the SUB may include a glass material or a metal material.

The buffer layer BF may be disposed on the substrate SUB. The buffer layer BF may include an inorganic material capable of preventing permeation of air or moisture. For example, the buffer layer BF may include inorganic layers laminated alternately.

The thin film transistor TFT may be disposed on the buffer layer BF, and may constitute a pixel circuit of each of the pixels SP. For example, the thin film transistor TFT may be a switching transistor or a driving transistor of the pixel circuit. The thin film transistor TFT may include a semiconductor region ACT, a drain electrode DE, a source electrode SE, and a gate electrode GE.

The semiconductor region ACT, the drain electrode DE, and the source electrode SE may be arranged on the buffer layer BF. The semiconductor region ACT may overlap the gate electrode GE in a thickness direction of the display panel 100, and may be insulated (e.g., electrically insulated) from the gate electrode GE by the gate insulating layer GI. The drain electrode DE and the source electrode SE may be provided by making a material of the semiconductor region ACT conductive. For example, a portion of the semiconductor region ACT may be implanted by impurities to form the drain electrode DE and the source electrode SE.

The gate electrode GE may be disposed on the gate insulating layer GI. The gate electrode GE may overlap the semiconductor region ACT with the gate insulating layer GI interposed therebetween. For example, the gate insulating layer GI may be disposed between the gate electrode GE and the semiconductor region ACT in the third direction (or in the Z-axis direction).

The gate insulating layer GI may be disposed on the semiconductor region ACT, the drain electrode DE, and the source electrode SE. For example, the gate insulating layer GI may cover the semiconductor region ACT, the drain electrode DE, the source electrode SE, and the buffer layer BF, and may insulate the semiconductor region ACT and the gate electrode GE from each other.

The storage capacitor CST may include a first capacitor electrode CPE1 and a second capacitor electrode CPE2. The first capacitor electrode CPE1 may be disposed on the gate insulating layer GI, and the second capacitor electrode CPE2 may be disposed on the first interlayer insulating layer ILD1. The first and second capacitor electrodes CPE1 and CPE2 may overlap each other in the third direction (or in the Z-axis direction), so that a capacitance may be formed between the first and second capacitor electrodes CPE1 and CPE2.

The first interlayer insulating layer ILD1 may be disposed on the gate electrode GE, the first capacitor electrode CPE1, and the gate insulating layer GI. The second interlayer insulating layer ILD2 may be disposed on the second capacitor electrode CPE2 and the first interlayer insulating layer ILD1. The first and second interlayer insulating layers ILD1 and ILD2 and the gate insulating layer GI may include a contact hole through which the connection electrode CNE passes.

The connection electrode CNE may be disposed on the second interlayer insulating layer ILD2. The connection electrode CNE may electrically connect the source electrode SE of the thin film transistor TFT to the first electrode RME1. The connection electrode CNE may be connected to the source electrode SE through the contact hole provided in the first and second interlayer insulating layers ILD1 and ILD2 and the gate insulating layer GI.

The voltage line VL may be disposed on the second interlayer insulating layer ILD2 and may be spaced apart from the connection electrode CNE. The voltage line VL may be connected to the second electrode RME2 inserted into the fourth contact hole CNT4. The voltage line VL may be a low potential line that supplies a low potential voltage to the second electrode RME2, but is not limited thereto.

The planarization layer OC may be disposed on the connection electrode CNE, the voltage line VL, and the second interlayer insulating layer ILD2 and planarize a top end of the thin film transistor TFT. The planarization layer OC may include the first contact hole CNT1 through which the first electrode RME1 passes and the fourth contact hole CNT4 through which the second electrode RME2 passes. The planarization layer OC may include an organic material.

The bank pattern BP may be disposed on the planarization layer OC. At least a part of the bank pattern BP may protrude from a top surface of the planarization layer OC. The bank patterns BP may be disposed in the first opening area OA1 of each of the pixels SP. The light emitting elements ED may be disposed between the bank patterns BP. The bank pattern BP may have inclined side surfaces, and the light emitted from the light emitting elements ED may be reflected by the first and second electrodes RME1 and RME2 arranged on the bank patterns BP. For example, the bank pattern BP may include an organic insulating material such as polyimide (PI).

The first electrode RME1 may be disposed on the planarization layer OC and the bank pattern BP. The first electrode RME1 may be disposed on the bank pattern BP located on a side of the light emitting elements ED. The first electrode RME1 may be disposed on the inclined surfaces (e.g., the inclined side surfaces) of the bank pattern BP and reflect the light emitted from the light emitting element ED. The first electrode RME1 may be inserted into the first contact hole CNT1 provided in the planarization layer OC and may be electrically connected to the connection electrode CNE. The first electrode RME1 may be electrically connected to an end of the light emitting element ED through the first contact electrode CTE1. For example, the first electrode RME1 may receive a voltage that is proportional to a luminance of the light emitting element ED from the pixel circuit of the pixel SP.

The second electrode RME2 may be disposed on the planarization layer OC and the bank pattern BP. The second electrode RME2 may be disposed on the bank pattern BP located on another side of the light emitting elements ED. The second electrode RME2 may be disposed on the inclined surfaces of the bank pattern BP and reflect the light emitted from the light emitting element ED. The second electrode RME2 may be electrically connected to the another end of the light emitting element ED through the second contact electrode CTE2. For example, the second electrode RME2 may receive a low potential voltage supplied to all pixels SP from the voltage line VL.

The first and second electrodes RME1 and RME2 may contain a conductive material having high reflectivity. For example, the first and second electrodes RME1 and RME2 may contain at least one of silver (Ag), copper (Cu), aluminum (Al), nickel (Ni), and lanthanum (La). In an embodiments, the first and second electrodes RME1 and RME2 may contain a material such as ITO, IZO, ITZO, or the like. In other embodiments, the first and second electrodes RME1 and RME2 may contain layers including a transparent conductive material layer and a metal layer having high reflectivity, or may include a layer containing a transparent conductive material or a metal having high reflectivity. The first and second electrodes RME1 and RME2 may have a stacked structure of ITO/Ag/ITO, ITO/Ag/IZO, ITO/Ag/ITZO/IZO, or the like.

The first insulating layer PAS1 may be disposed on the planarization layer OC and the first and second electrodes RME1 and RME2. The first insulating layer PAS1 may protect and insulate (e.g., electrically insulate) the first electrode RME1 and the second electrode RME2 from each other. The first insulating layer PAS1 may prevent damage caused by direct contact between the light emitting element ED and the first and second electrodes RME1 and RME2 in the alignment process of the light emitting element ED.

The bank SB may be disposed on the first insulating layer PAS1 between the first and second opening areas OA1 and OA2. The bank SB may be disposed at a boundary of the pixels SP and distinguish the light emitting elements ED of each of the pixels SP. The bank SB may have a height (e.g., a predetermined height or selectable height) and may contain an organic insulating material such as polyimide (PI).

The light emitting elements ED may be arranged on the first insulating layer PAS1. The light emitting elements ED may be arranged in parallel to each other between the first electrode RME1 and the second electrodes RME2. A length of the light emitting element ED may be greater than a length (or distance) between the first electrode RME1 and the second electrodes RME2. The light emitting element ED may include semiconductor layers, and an end and another end opposite to the end may be defined with respect to any one semiconductor layer. The end of the light emitting element ED may be disposed on the first electrode RME1, and the another end of the light emitting element ED may be disposed on the second electrode RME2. The end of the light emitting element ED may be electrically connected to the first electrode RME1 through the first contact electrode CTE1, and the another end of the light emitting element ED may be electrically connected to the second electrode RME2 through the second contact electrode CTE2.

The light emitting element ED may have a micro-meter or nano-meter size, and may be an inorganic light emitting diode including an inorganic material. The light emitting element ED may be aligned between the first electrode RME1 and the second electrode RME2 facing each other by the electric field formed in a direction between the first electrode RME1 and the second electrode RME2.

The second insulating layer PAS2 may be disposed on the light emitting elements ED, the bank SB, and the first insulating layer PAS1.For example, the second insulating layer PAS2 may be adjacent to (e.g., partially surround) the light emitting elements ED and may not cover both ends of the light emitting elements ED. The second insulating layer PAS2 may protect the light emitting elements ED, and may fix the light emitting elements ED in the manufacturing process of the display device 10. The second insulating layer PAS2 may fill a space between the light emitting element ED and the first insulating layer PAS1.

The first contact electrode CTE1 may be disposed on the first insulating layer PAS1. The first contact electrode CTE1 may be inserted into the second contact hole CNT2 provided in the first insulating layer PAS 1, and may be electrically connected to the first electrode RME1. For example, the second contact hole CNT2 may be provided above the bank pattern BP, but is not limited thereto. An end of the first contact electrode CTE1 may be electrically connected to the first electrode RME1 on the bank pattern BP, and another end of the first contact electrode CTE1 may be electrically connected to an end of the light emitting element ED.

The second contact electrode CTE2 may be disposed on the first insulating layer PAS 1. The second contact electrode CTE2 may be inserted into the third contact hole CNT3 provided in the first insulating layer PAS1, and may be electrically connected to the second electrode RME2. For example, the third contact hole CNT3 may be provided above the bank pattern BP, but is not limited thereto. An end of the second contact electrode CTE2 may be electrically connected to the another end of the light emitting element ED, and another end of the second contact electrode CTE2 may be electrically connected to the second electrode RME2 on the bank pattern BP.

The third insulating layer PAS3 may be disposed on the first contact electrode CTE1 and the second insulating layer PAS2. The third insulating layer PAS3 may insulate (e.g., electrically insulate) the first and second contact electrodes CTE1 and CTE2 from each other.

The wavelength conversion layer QDL may be disposed on the third insulating layer PAS3 and the second contact electrode CTE2 in the first opening area OA1. The wavelength conversion layer QDL may be adjacent to (e.g., surrounded by) the bank SB in a plan view. The wavelength conversion layer QDL may convert or shift a peak wavelength of incident light. For example, the wavelength conversion layer QDL may convert the blue light provided from the light emitting elements ED into red light or green light and may emit the converted light. In other embodiments, the wavelength conversion layer QDL may transmit the blue light provided from the light emitting elements ED.

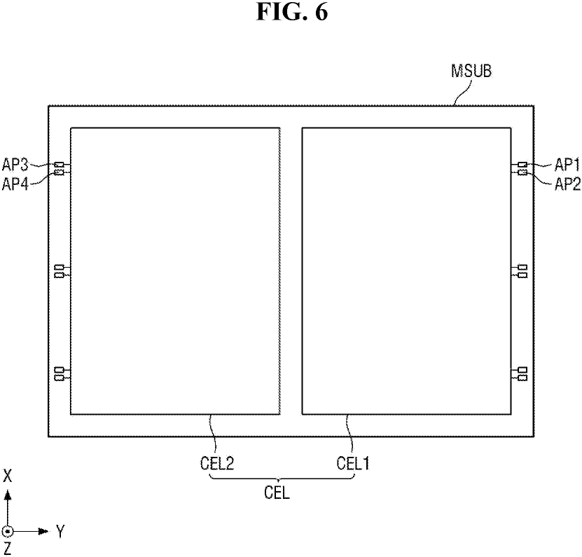

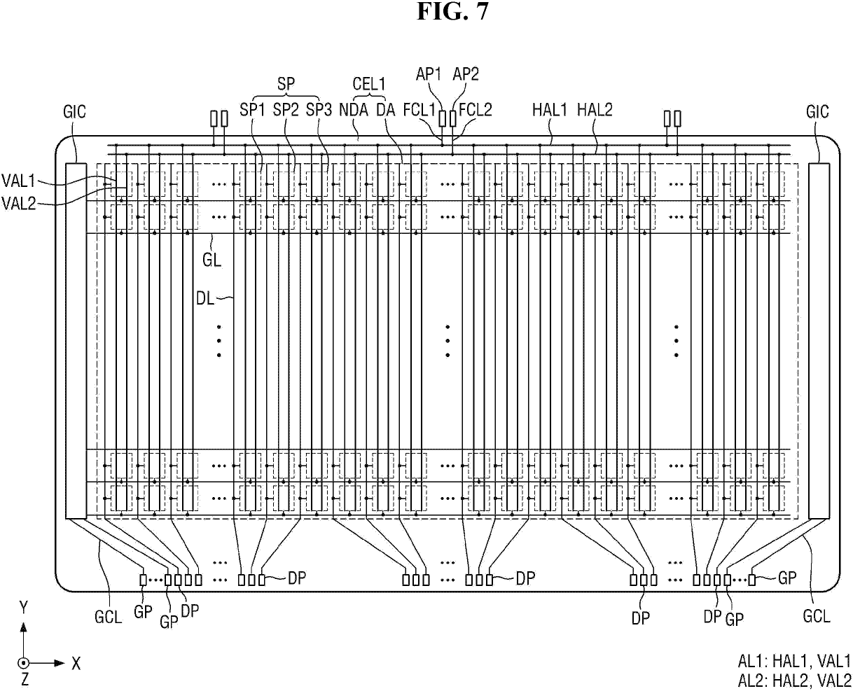

FIG. 6 is a schematic plan view illustrating a mother substrate according to an embodiment. FIG. 7 is a schematic plan view illustrating a panel cell of FIG. 6. Hereinafter, the same configuration as the above-described configuration will be briefly described, or a description thereof will be omitted.

Referring to FIGS. 6 and 7, a mother substrate MSUB may include a first panel cell CEL1, a second panel cell CEL2, a first alignment pad AP1, a second alignment pad AP2, a third alignment pad AP3, and a fourth alignment pad AP4. Although the mother substrate MSUB may include the first and second panel cells CEL1 and CEL2, the number of the panel cells CEL1 and CEL2 of the mother substrate MSUB is not limited thereto.

The first panel cell CEL1 may be disposed on a first side of the mother substrate MSUB, and the second panel cell CEL2 may be disposed on a second side of the mother substrate MSUB. The first panel cell CEL1 and the second panel cell CEL2 may be symmetrical with respect to an axis in the second direction (or in the Y-axis direction). The first and second alignment pads AP1 and AP2 and the third and fourth alignment pads AP3 and AP4 may be symmetrical with respect to the axis in the second direction (or in the Y-axis direction). For example, the first and second alignment pads AP1 and AP2 may be disposed on a right side of the first panel cell CEL1, and the third and fourth alignment pads AP3 and AP4 may be disposed to a left side of the second panel cell CEL2.

In FIG. 7, the first panel cell CEL1 may include the pixels SP, the gate driver GIC, the gate line GL, the data line DL, a first alignment line AL1, a second alignment line AL2, the first connection line FCL1, the second connection line FCL2, the display pad portion DP, and the gate pad portion GP.

The first alignment line AL1 may include a first horizontal alignment line HAL1 and a first vertical alignment line VAL1. The first horizontal alignment line HAL1 may be substantially the same as the first floating line FL1 of FIG. 2. The first horizontal alignment line HAL1 may be electrically connected to the first alignment pad AP1 through the first connection line FCL1. The first vertical alignment line VAL1 may extend from the first horizontal alignment line HAL1 in a direction opposite to the second direction (or in the Y-axis direction). The first vertical alignment line VAL1 may be electrically connected to the first to third pixels SP1, SP2, and SP3 arranged in the second direction (or in the Y-axis direction).

The second alignment line AL2 may include a second horizontal alignment line HAL2 and a second vertical alignment line VAL2. The second horizontal alignment line HAL2 may be substantially the same as the second floating line FL2 of FIG. 2. The second horizontal alignment line HAL2 may be electrically connected to the second alignment pad AP2 through the second connection line FCL2. The second vertical alignment line VAL2 may extend from the second horizontal alignment line HAL2 in the direction opposite to the second direction (or in the Y-axis direction). The second vertical alignment line VAL2 may be electrically connected to the first to third pixels SP1, SP2, and SP3 arranged in the second direction (or in the Y-axis direction).

The first alignment line AL1 may be electrically connected to the first alignment pad AP1 through the first connection line FCL1, and the second alignment line AL2 may be electrically connected to the second alignment pad AP2 through the second connection line FCL2. The first and second vertical alignment lines VAL1 and VAL2 may be disposed in all pixels SP of the display panel 100. A first alignment signal may be applied to the first alignment line AL1 through the first alignment pad AP1, and a second alignment signal may be applied to the second alignment line AL2 through the second alignment pad AP2. The light emitting elements ED may be aligned between the first and second vertical alignment lines VAL1 and VAL2 by an electric field formed by the first alignment signal of the first alignment line AL1 and the second alignment signal of the second alignment line AL2.

The first and second vertical alignment lines VAL1 and VAL2 may be disconnected after the light emitting elements ED are completely aligned. Accordingly, the first vertical alignment line VAL1 may be separated into the third connection line FCL3 and the first electrodes RME1 shown in FIG. 2, and the second vertical alignment line VAL2 may be separated into the fourth connection line FCL4 and the second electrodes RME2 shown in FIG. 2.

The first and second panel cells CEL1 and CEL2 may be cut by a scribing process. Accordingly, each of the first and second panel cells CEL1 and CEL2 may be formed of the display panel 100 shown in FIG. 2.

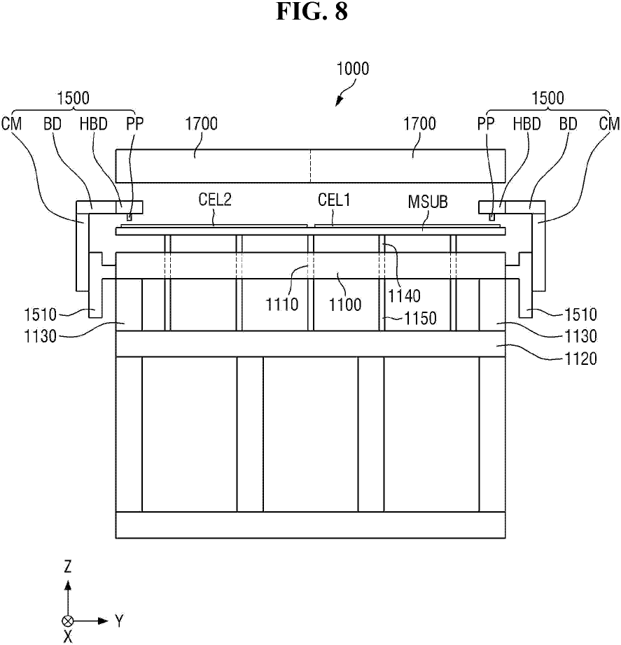

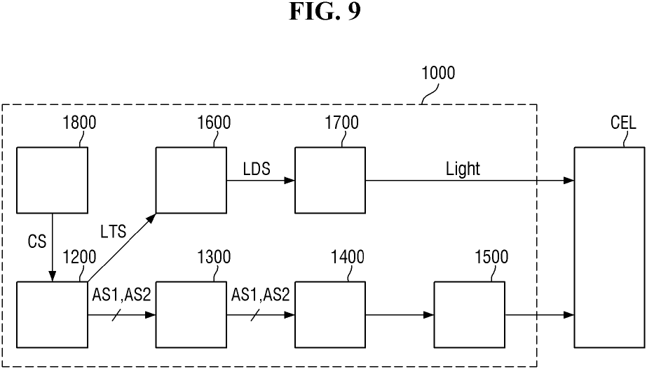

FIG. 8 is a schematic cross-sectional view illustrating an apparatus for manufacturing a display device according to an embodiment. FIG. 9 is a schematic block diagram illustrating an apparatus for manufacturing a display device according to an embodiment.

Referring to FIGS. 8 and 9, an apparatus 1000 for manufacturing a display device may supply an alignment signal to each of the panel cells CEL. The apparatus 1000 for manufacturing the display device may supply the alignment signal to the first panel cell CEL1 through the first and second alignment pads AP1 and AP2 and may supply the alignment signal to the second panel cell CEL2 through the third and fourth alignment pads AP3 and AP4. The apparatus 1000 for manufacturing the display device may supply the alignment signal to the first and second panel cells CEL1 and CEL2 and align the light emitting elements ED in the first to third pixels SP1, SP2 and SP3.

The apparatus 1000 for manufacturing the display device may include a stage 1100, a stage hole 1110, a stage support 1120, a stage moving part 1130, a support pin 1140, a pin support 1150, and a voltage output part 1200, an amplifier 1300, a switching part 1400, an electric field applying part 1500, a probe moving part 1510, an emission driver 1600, a light irradiation part 1700, and a controller 1800.

The stage 1100 may have a flat top surface and stably support the mother substrate MSUB. The stage 1100 may be raised or lowered by the stage moving part 1130. The stage 1100 may include the stage hole 1110 passing therethrough. The support pin 1140 and the pin support 1150 may pass through the stage hole 1110. The stage holes 1110 may be arranged in the first direction (or in the X-axis direction) and the second direction (or in the Y-axis direction). For example, the stage holes 1110 may be arranged at a first interval in the first direction (or in the X-axis direction) and at a second interval in the second direction (or in the Y-axis direction).

The stage support 1120 may be disposed under the stage 1100 and support the stage 1100. The stage moving part 1130 and the pin support 1150 may be disposed on the stage support 1120. The stage support 1120 may have various shapes.

The stage moving part 1130 may be coupled to (e.g., be mechanically coupled to) the lower portion of the stage 1100. The stage moving part 1130 may support a lower edge of the stage 1100. The stage moving part 1130 may raise or lower the stage 1100 based on a stage control signal of the controller 1800. The stage moving part 1130 may include a motor as a power source for moving the stage 1100.

In case that the stage control signal of a first voltage level is received from the controller 1800, the stage moving part 1130 may raise the stage 1100 to a height (e.g., a preset height or selectable height). In case that the stage control signal of a second voltage level is received from the controller 1800, the stage moving part 1130 may lower the stage 1100 to a height (e.g., a preset height or selectable height).

The support pin 1140 may support the mother substrate MSUB during a process of inserting or withdrawing the mother substrate MSUB into or out of the apparatus 1000 for manufacturing the display device. The support pin 1140 may be connected to the pin support 1150 disposed under the stage 1100 through the stage hole 1110 of the stage 1100.

In case that the stage 1100 is lowered by the stage moving part 1130, the support pin 1140 may protrude from a top surface of the stage 1100. In case that the stage 1100 is raised by the stage moving part 1130, the support pin 1140 may be disposed within the stage hole 1110, and may not protrude from the top surface of the stage 1100. Accordingly, in case that the stage 1100 is raised by the stage moving part 1130, the mother substrate MSUB may be seated on the top surface of the stage 1100.

The voltage output part 1200 may generate an electric field signal based on a control signal CS received from the controller 1800 and supply the electric field signal to the amplifier 1300. The electric field signal may include a first alignment signal AS1 and a second alignment signal AS2. Referring to FIGS. 7 and 9, the first alignment signal AS1 may be applied to the first alignment line AL1 of the panel cell CEL through the first alignment pad AP1, and the second alignment signal AS2 may be applied to the second alignment line AL2 of the panel cell CEL through the second alignment pad AP2. The voltage output part 1200 may generate an emission timing signal LTS based on the control signal CS received from the controller 1800 and supply the emission timing signal LTS to the emission driver 1600. For example, the first alignment signal AS1, the second alignment signal AS2, and the emission timing signal LTS may be AC signals or DC signals. The voltage output part 1200 may synchronize the first and second alignment signals AS1 and AS2 and the emission timing signal LTS and provide the first and second alignment signals AS1 and AS2 to the amplifier 1300. For example, the first alignment signal AS1 and the emission timing signal LTS may have a same frequency and may be controlled to have a phase difference (e.g., a preset phase difference or selectable phase difference).

The voltage output part 1200 may include a function generator. The voltage output part 1200 may output at least one of a sine wave, a square wave, a triangle wave, a pulse wave, a sawtooth wave, a sawtooth composite wave, and a reverse sawtooth composite wave having a frequency (e.g., a predetermined frequency or selectable frequency). For example, the sawtooth composite wave may include sawtooth waves having different frequencies or amplitudes. The reverse sawtooth composite wave may include reverse sawtooth waves having different frequencies or amplitudes. The voltage output part 1200 may determine the type, amplitude, and frequency of an output waveform based on the control signal CS.

The amplifier 1300 may receive the first and second alignment signals AS1 and AS2 from the voltage output part 1200. The amplifier 1300 may amplify at least one of the first and second alignment signals AS1 and AS2 and supply the amplified one of the first and second alignment signals AS1 and AS2 to the switching part 1400. Accordingly, amplitudes of the first and second alignment signals AS1 and AS2 outputted from the amplifier 1300 may be greater than amplitudes of the first and second alignment signals AS1 and AS2 outputted from the voltage output part 1200. For example, when the second alignment signal AS2 is a ground voltage or a DC voltage close to the ground voltage, the amplifier 1300 may not amplify the second alignment signal AS2.

The switching part 1400 may be electrically connected to the amplifier 1300. The switching part 1400 may include at least one switch or at least one multiplexer. The switching part 1400 may receive the first and second alignment signals AS1 and AS2 from the amplifier 1300 in the alignment process of the light emitting element ED. The switching part 1400 may receive the first and second alignment signals AS1 and AS2 and supply the first and second alignment signals AS1 and AS2 to the electric field applying part 1500. For example, the switching part 1400 may collectively supply the first and second alignment signals AS1 and AS2 to multiple electric field applying parts 1500. In other embodiments, the switching part 1400 may selectively supply the first and second alignment signals AS1 and AS2 to some of the electric field applying parts 1500.

The electric field applying part 1500 may be disposed on sides (e.g., both sides) of the stage 1100. The electric field applying part 1500 may be disposed on a first side of the stage 1100 and supply the electric field signal to the first panel cell CEL1. The electric field applying part 1500 may be disposed on a second side of the stage 1100 and supply the electric field signal to the second panel cell CEL2. The electric field applying part 1500 may include a probe head HBD, a probe pin PP, a body part BD, and a coupling part CM.

The probe pin PP may be disposed under the probe head HBD. The probe pin PP may include a material, e.g., a metal material, having high conductivity. The number of the probe pins PP may correspond to the number of the first to fourth alignment pads AP1, AP2, AP3, and AP4 on the mother substrate MSUB. Accordingly, the probe pins PP may be electrically connected to the first to fourth alignment pads AP1, AP2, AP3, and AP4 in the alignment process of the light emitting element ED.

The body part BD may extend in the second direction (or in the Y-axis direction). The body part BD may be disposed between the probe head HBD and the coupling part CM. An end of the body part BD may be supported by the coupling part CM, and another end of the body part BD may support the probe head HBD. The body part BD may move vertically by the probe moving part 1510 together with the coupling part CM, and may supply the electric field signal to the probe head HBD. For example, the body part BD and the probe head HBD may be integral with each other. In other embodiments, the body part BD and the probe head HBD may be configured separately.

The coupling part CM may extend in the third direction (on in the Z-axis direction). The coupling part CM may be disposed under the body part BD. The coupling part CM may protrude from an end of the body part BD in a direction opposite to the third direction (or in the Z-axis direction). The coupling part CM may be disposed between the body part BD and the probe moving part 1510. The coupling part CM may move vertically by the probe moving part 1510.

The probe moving part 1510 may be coupled to a side surface of the stage 1100. The probe moving part 1510 may raise or lower the electric field applying part 1500 based on a module movement signal of the controller 1800. The probe moving part 1510 may include a motor as a power source for moving the electric field applying part 1500.

In case that the module movement signal of the first voltage level is received from the controller 1800, the probe moving part 1510 may raise the electric field applying part 1500 to a height (e.g., a preset height or selectable height). In case that the module movement signal of the second voltage level is received from the controller 1800, the probe moving part 1510 may lower the electric field applying part 1500 to a height (e.g., a preset height or selectable height).

In case that the probe moving part 1510 descends, the probe pin PP may be brought into contact with the first and second alignment pads AP1 and AP2 electrically connected to the first panel cell CEL1 of the mother substrate MSUB. The first and second alignment signals AS1 and AS2 may be applied to the first panel cell CEL1 on the mother substrate MSUB through the probe pin PP. Accordingly, the light emitting elements ED of the pixels SP in the first panel cell CEL1 may be aligned. In case that the probe moving part 1510 ascends, the probe pin PP may be spaced apart from the first and second alignment pads AP1 and AP2 of the mother substrate SUB.

The emission driver 1600 may receive the emission timing signal LTS from the voltage output part 1200 and supply an emission driving signal LDS to the light irradiation part 1700. The light irradiation part 1700 may include light emitting diodes, and may output light having a duty ratio (e.g., a predetermined duty ratio or selectable duty ratio) based on the emission driving signal LDS. Accordingly, the voltage output part 1200 may control the supply timing of the emission driving signal LDS using the emission timing signal LTS, thereby controlling the light irradiation timing of the light irradiation part 1700.

The light irradiation part 1700 may be disposed above the stage 1100 and may include light emitting diodes. The light irradiation part 1700 may irradiate light toward the panel cells CEL disposed on the stage 1100. The light irradiation part 1700 may cover the top surface (e.g., the entire top surface) of the stage 1100 or a top surface (e.g., an entire top surface) of the mother substrate MSUB. For example, an area of the light irradiation part 1700 may be greater than an area of the stage 1100 or an area of the mother substrate MSUB. In other embodiments, lengths of the light irradiation part 1700 in the first direction (or in the X-axis direction) and in the second direction (or in the Y-axis direction) may be greater than lengths of the stage 1100 in the first direction (or in the X-axis direction) and in the second direction (or in the Y-axis direction). The lengths of the light irradiation part 1700 in the first direction (or in the X-axis direction) and in the second direction (or in the Y-axis direction) may be greater than lengths of the mother substrate MSUB in the first direction (or in the X-axis direction) and in the second direction (or in the Y-axis direction).

For example, the light irradiation part 1700 may irradiate light to the first and second panel cells CEL1 and CEL2 on the mother substrate MSUB. In case that the light irradiation part 1700 irradiates the light to the first and second panel cells CEL1 and CEL2, the electric field applying part 1500 may collectively supply the alignment signal to the first and second panel cells CEL1 and CEL2. In other embodiments, the light irradiation part 1700 may selectively irradiate light to a panel cell CEL (e.g., the first panel cell CEL1 or the second panel cell CEL2) of the first and second panel cells CEL1 and CEL2. In case that the light irradiation part 1700 irradiates the light to some of the panel cells CEL, the electric field applying part 1500 may selectively supply the alignment signal to the corresponding cells CEL.

The light emitting element ED may include a p-type first semiconductor layer, an n-type second semiconductor layer, and an active layer. The active layers of the light emitting elements ED may have an excited state by the light of the light irradiation part 1700. Holes in the p-type doped first semiconductor layer of the light emitting element ED may move to the n-type doped second semiconductor layer, and electrons in the n-type doped second semiconductor layer may move to the p-type doped first semiconductor layer. A permanent dipole moment may be strongly generated in a direction from the p-type doped first semiconductor layer to the n-type doped second semiconductor layer. Accordingly, in case that the light emitting element ED has an excited state by the light of the light irradiation part 1700, the light emitting element ED may be defined as a particle having a polarity in the longitudinal direction.

The controller 1800 may control operations of all components of the apparatus 1000 for manufacturing the display device. The controller 1800 may supply the stage control signal to the stage moving part 1130 and control the vertical movement of the stage 1100. The controller 1800 may supply the control signal CS to the voltage output part 1200 and determine the waveforms of the first and second alignment signals AS1 and AS2. Waveforms of the first and second alignment signals AS1 and AS2 may be determined based on a type, an amplitude, and a frequency. The controller 1800 may supply the module movement signal to the probe moving part 1510 and control the vertical movement of the electric field applying part 1500. The controller 1800 may supply the emission timing signal LTS to the emission driver 1600 and control the driving timing of the light irradiation part 1700.

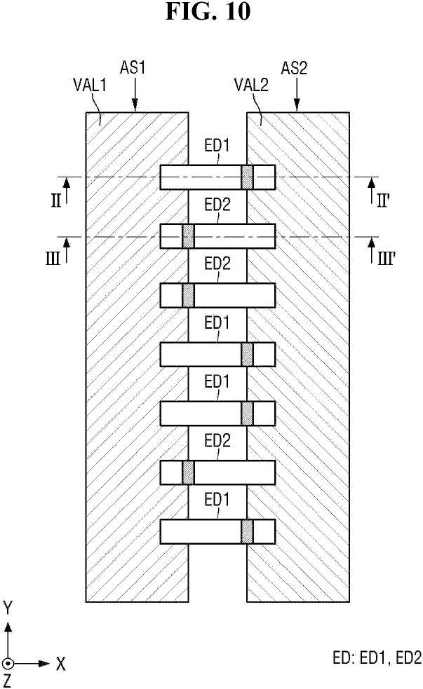

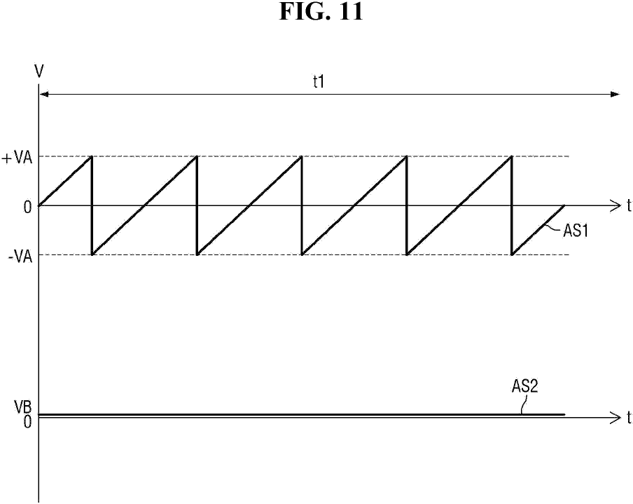

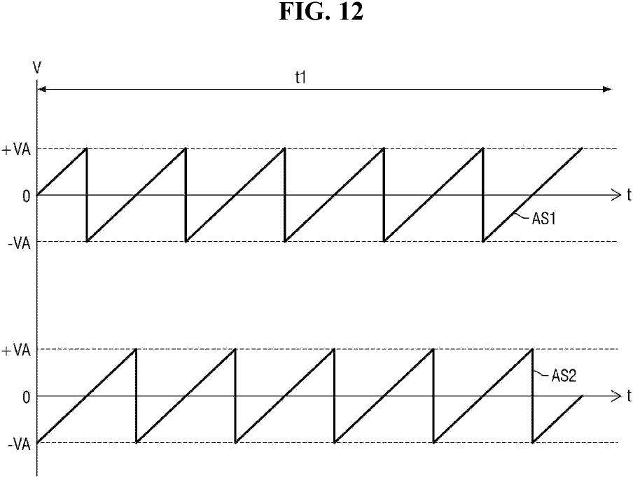

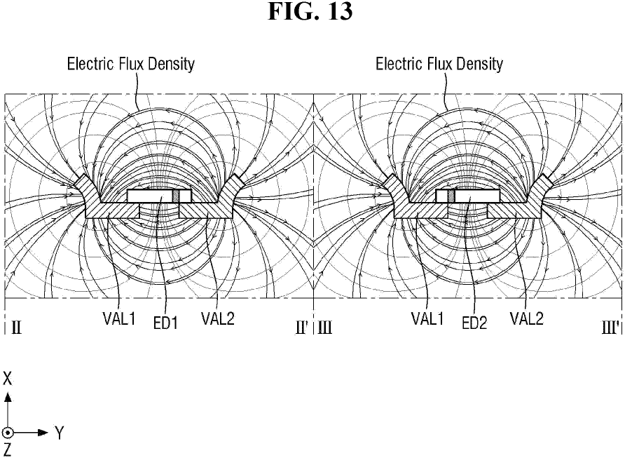

FIG. 10 is a schematic plan view illustrating first and second vertical alignment lines and light emitting elements in a first period in a manufacturing process of a display device according to an embodiment. FIG. 11 is a schematic waveform diagram illustrating first and second alignment signals in the manufacturing process of the display device of FIG. 10 according to an embodiment. FIG. 12 is a schematic waveform diagram illustrating first and second alignment signals in the manufacturing process of the display device of FIG. 10 according to an embodiment. FIG. 13 is a schematic cross-sectional view taken along lines II-II′ and III-III′ of FIG. 10.

Referring to FIGS. 9 to 13, the controller 1800 may supply the control signal CS to the voltage output part 1200 and determine the types, amplitudes, and frequencies of the first and second alignment signals AS1 and AS2. Based on the control signal CS received from the controller 1800, the voltage output part 1200 may generate the first and second alignment signals AS1 and AS2 and supply the first and second alignment signals AS1 and AS2 to the amplifier 1300. The amplifier 1300 may amplify at least one of the first and second alignment signals AS1 and AS2 and supply the amplified signal (e.g., the amplified at least one of the first and second alignment signals AS1 and AS2) to the switching part 1400. The switching part 1400 may selectively supply the first and second alignment signals AS1 and AS2 to at least some of the electric field applying parts 1500. The electric field applying part 1500 may supply the first and second alignment signals AS1 and AS2 to the first and second panel cells CEL1 and CEL2 through the first to fourth alignment pads AP1, AP2, AP3, and AP4.

The first and second vertical alignment lines VAL1 and VAL2 may be disposed in all pixels SP of the display panel 100. The first vertical alignment line VAL1 may receive the first alignment signal AS1 through the first alignment pad AP1 during a first period t1, and the second vertical alignment line VAL2 may receive the second alignment signal AS2 through the second alignment pad AP2 during the first period t1. The first and second alignment signals AS1 and AS2 may have a potential difference (e.g., a predetermined potential difference or selectable potential difference) during the first period t1.

In FIG. 11, the first alignment signal AS1 may be a sawtooth wave having a frequency (e.g., a predetermined frequency or selectable frequency) and swinging between a first positive voltage +VA and a first negative voltage -VA, but is not limited thereto. The second alignment signal AS2 may be a DC voltage of a second voltage VB. The second voltage VB may be a ground voltage or a DC voltage close to the ground voltage, but is not limited thereto. In other embodiments, the first alignment signal AS1 or the second alignment signal AS2 may be one of a sine wave, a square wave, a triangle wave, a pulse wave, a sawtooth composite wave, and a reverse sawtooth composite wave. The first and second alignment signals AS1 and AS2 may have a potential difference (e.g., a predetermined potential difference or selectable potential difference).

In FIG. 12, the first and second alignment signals AS1 and AS2 may be sawtooth waves having a frequency (e.g., a predetermined frequency or selectable frequency) and swinging between the first positive voltage +VA and the first negative voltage -VA, and may have different phases from each other. For example, the first and second alignment signals AS1 and AS2 may have opposite phases, but are not limited thereto.

In case that the first and second alignment signals AS1 and AS2 have a potential difference (e.g., a predetermined potential difference or selectable potential difference), an electric field may be formed between the first and second vertical alignment lines VAL1 and VAL2. In case that the potential difference occurs while the first and second vertical alignment lines VAL1 and VAL2 have an electric charge (e.g., a predetermined electric charge or selectable electric charge), electric flux density may be formed adjacent to (e.g., formed around) the first and second vertical alignment lines VAL1 and VAL2. For example, electric streamlines may extend from the second vertical alignment line VAL2 to the first vertical alignment line VAL1. The electric flux density may be highest at the shortest distance from the first and second vertical alignment lines VAL1 and VAL2, and may decrease as the distance from the first and second vertical alignment lines VAL1 and VAL2 increases. A force by an induced dipole may pull the light emitting element ED toward the first and second vertical alignment lines VAL1 and VAL2 during the first period t1. A force by a permanent dipole may pull the light emitting element ED toward the first and second vertical alignment lines VAL1 and VAL2, or push the light emitting element ED from the first and second vertical alignment lines VAL1 and VAL2 during the first period t1. The force by the induced dipole may be greatest between the first and second vertical alignment lines VAL1 and VAL2, and may be greater than the force by the permanent dipole, during the first period t1. The light emitting element ED may be pulled toward the first and second vertical alignment lines VAL1 and VAL2 by the electric field.

Accordingly, the light emitting elements ED may be aligned by the electric field adjacent to (e.g., formed around) the first and second vertical alignment lines VAL1 and VAL2. Some of the light emitting elements ED may be aligned in a positive deflection, and another of the light emitting elements ED may be aligned in a negative deflection. The light emitting elements ED aligned in the positive deflection may be first light emitting elements ED1, and the light emitting elements ED aligned in the negative deflection may be second light emitting elements ED2. For example, when a first semiconductor layer 111 of the light emitting element ED is adjacent to the second vertical alignment line VAL2, the light emitting element ED may be in the positive deflection. In case that the first semiconductor layer 111 of the light emitting element ED is adjacent to the first vertical alignment line VAL1, the light emitting element ED may be in the negative deflection, but the disclosure is not limited thereto.

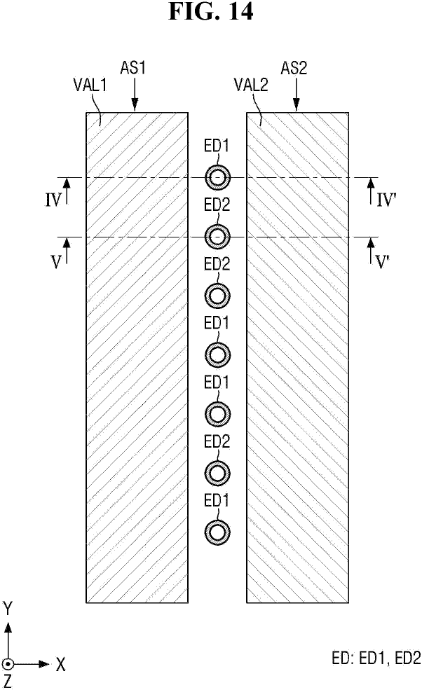

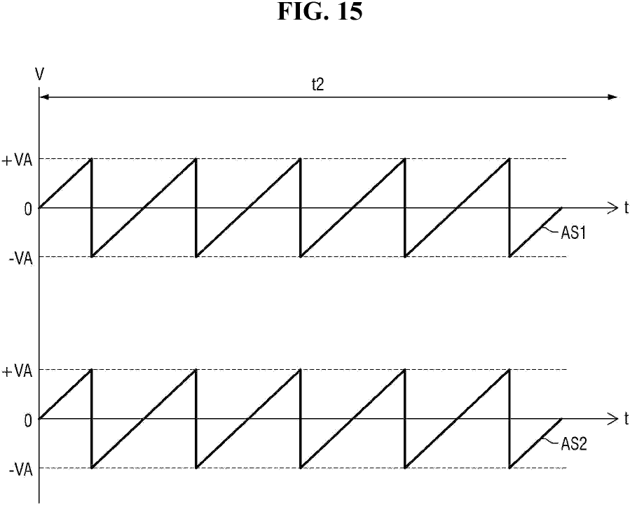

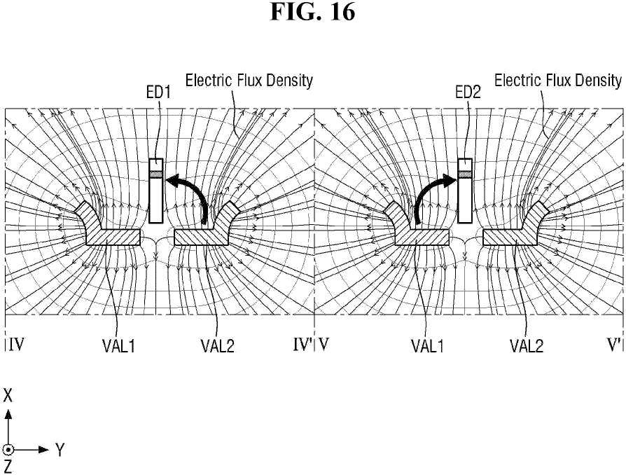

FIG. 14 is a schematic plan view illustrating first and second vertical alignment lines and light emitting elements in a second period in a manufacturing process of a display device according to an embodiment. FIG. 15 is a schematic waveform diagram illustrating first and second alignment signals in the manufacturing process of the display device of FIG. 14. FIG. 16 is a schematic cross-sectional view taken along lines IV-IV′ and V-V′ of FIG. 14.

Referring to FIGS. 14 to 16, the first vertical alignment line VAL1 may receive the first alignment signal AS1 through the first alignment pad AP1 during the second period t2 after the first period t1, and the second vertical alignment line VAL2 may receive the second alignment signal AS2 through the second alignment pad AP2 during the second period t2. The first and second alignment signals AS1 and AS2 may have a same potential during the second period t2, and a potential difference may not occur between the first and second alignment signals AS1 and AS2. In FIG. 15, the first and second alignment signals AS1 and AS2 may be sawtooth waves having a same frequency and phase and swinging between the first positive voltage +VA and the first negative voltage -VA, but are not limited thereto. In other embodiments, the first alignment signal AS1 or the second alignment signal AS2 may be one of a sine wave, a square wave, a triangle wave, a pulse wave, a sawtooth composite wave, and a reverse sawtooth composite wave. The first and second alignment signals AS1 and AS2 may be a same signal.

In case that the first and second alignment signals AS1 and AS2 do not have the potential difference, an electric field may be formed between the first and second vertical alignment lines VAL1 and VAL2. In case that the potential difference does not occur and the first and second vertical alignment lines VAL1 and VAL2 have an electric charge (e.g., a predetermined electric charge or selectable electric charge), electric flux density may be formed adjacent to (e.g., formed around) the first and second vertical alignment lines VAL1 and VAL2. For example, electric streamlines may move away from the first and second vertical alignment lines VAL1 and VAL2. The force by the induced dipole may pull the light emitting element ED toward the first and second vertical alignment lines VAL1 and VAL2 during the second period t2. The force by the permanent dipole may pull the light emitting element ED toward the first and second vertical alignment lines VAL1 and VAL2, or push the light emitting element ED from the first and second vertical alignment lines VAL1 and VAL2 during the second period t2. The force by the induced dipole may be smallest between the first and second vertical alignment lines VAL1 and VAL2, and may be smaller than the force by the permanent dipole, during the second period t2. The light emitting element ED may be pushed from the first and second vertical alignment lines VAL1 and VAL2 by the electric field.

Accordingly, the light emitting elements ED may stand vertically by the electric field adjacent to (e.g., formed around) the first and second vertical alignment lines VAL1 and VAL2. For example, the first light emitting element ED1 aligned in the positive deflection and the second light emitting element ED2 aligned in the negative deflection may stand vertically during the second period t2.

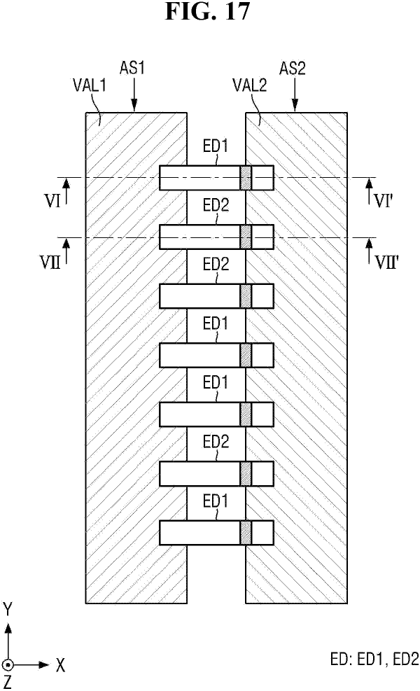

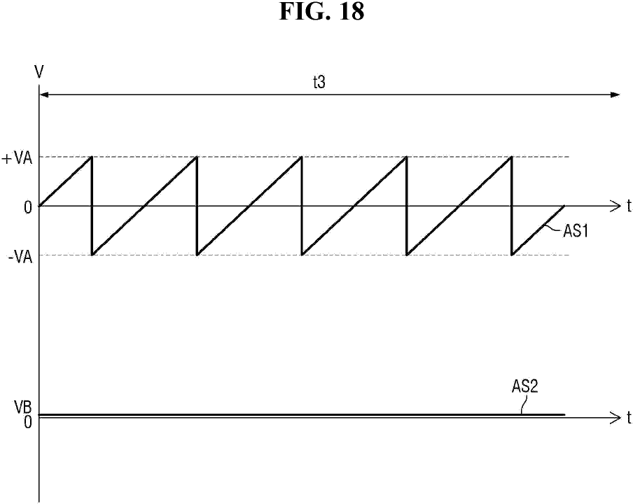

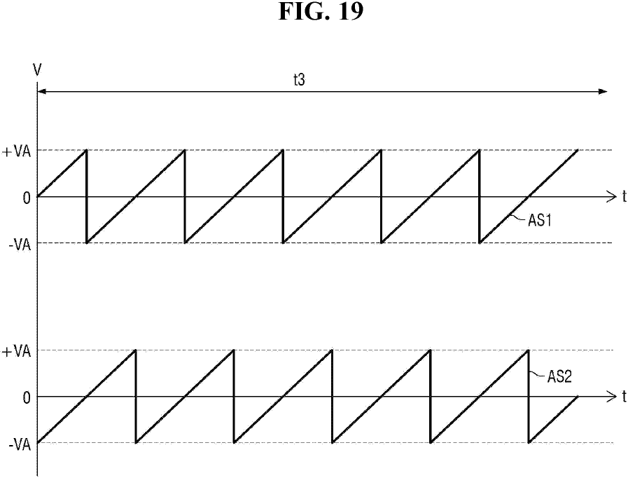

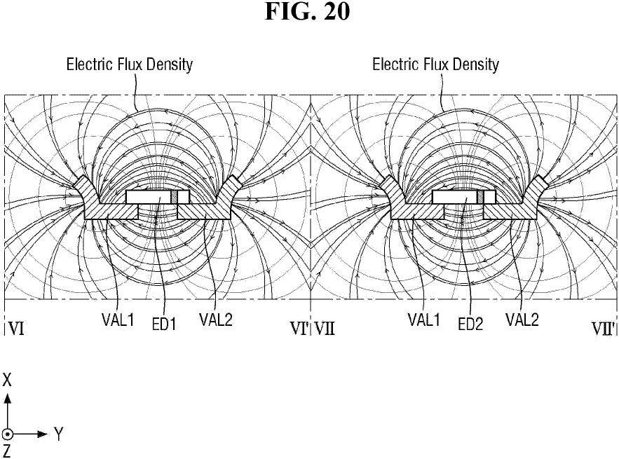

FIG. 17 is a schematic plan view illustrating first and second vertical alignment lines and light emitting elements in a third period in a manufacturing process of a display device according to an embodiment. FIG. 18 is a schematic waveform diagram illustrating first and second alignment signals in the manufacturing process of the display device of FIG. 17 according to an embodiment. FIG. 19 is a schematic waveform diagram illustrating first and second alignment signals in the manufacturing process of the display device of FIG. 17 according to an embodiment. FIG. 20 is a schematic cross-sectional view taken along lines VI-VI′ and VII′-VII′ of FIG. 17.

Referring to FIGS. 17 to 20, the first vertical alignment line VAL1 may receive the first alignment signal AS1 through the first alignment pad AP1 during the third period t3 after the second period t2, and the second vertical alignment line VAL2 may receive the second alignment signal AS2 through the second alignment pad AP2 during the third period t3. The first and second alignment signals AS1 and AS2 may have a potential difference (e.g., a predetermined potential difference or selectable potential difference) during the third period t3.

In FIG. 18, the first alignment signal AS1 may be a sawtooth wave having a frequency (e.g., a predetermined frequency or selectable frequency) and swinging between the first positive voltage +VA and the first negative voltage -VA, but is not limited thereto. The second alignment signal AS2 may be a DC voltage of the second voltage VB. The second voltage VB may be a ground voltage or a DC voltage close to the ground voltage, but is not limited thereto. In other embodiments, the first alignment signal AS1 or the second alignment signal AS2 may be one of a sine wave, a square wave, a triangle wave, a pulse wave, a sawtooth composite wave, and a reverse sawtooth composite wave. The first and second alignment signals AS1 and AS2 may have a potential difference (e.g., a predetermined potential difference or selectable potential difference).

In FIG. 19, the first and second alignment signals AS1 and AS2 may be sawtooth waves having a frequency (e.g., a predetermined frequency or selectable frequency) and swinging between the first positive voltage +VA and the first negative voltage -VA, and may have different phases from each other. For example, the first and second alignment signals AS 1 and AS2 may have opposite phases, but are not limited thereto.

In case that the first and second alignment signals AS1 and AS2 have a potential difference (e.g., a predetermined potential difference or selectable potential difference), an electric field may be formed between the first and second vertical alignment lines VAL1 and VAL2. In case that the potential difference occurs and the first and second vertical alignment lines VAL1 and VAL2 have an electric charge (e.g., a predetermined electric charge or selectable electric charge), electric flux density may be formed adjacent to (e.g., formed around) the first and second vertical alignment lines VAL1 and VAL2. For example, electric streamlines may extend from the second vertical alignment line VAL2 to the first vertical alignment line VAL1. The electric flux density may be highest at the shortest distance from the first and second vertical alignment lines VAL1 and VAL2, and may decrease as the distance from the first and second vertical alignment lines VAL1 and VAL2 increases. The force by the induced dipole may pull the light emitting element ED toward the first and second vertical alignment lines VAL1 and VAL2 during the third period t3. The force by the permanent dipole may pull the light emitting element ED toward the first and second vertical alignment lines VAL1 and VAL2 or push the light emitting element ED from the first and second vertical alignment lines VAL1 and VAL2 during the third period t3. The force by the induced dipole may be greatest between the first and second vertical alignment lines VAL1 and VAL2, and may be greater than the force by the permanent dipole, during the third period t3. The light emitting element ED may be pulled toward the first and second vertical alignment lines VAL1 and VAL2 by the electric field.

The light emitting elements ED that have stood up during the second period t2 may be aligned by the electric field adjacent to (e.g., formed around) the first and second vertical alignment lines VAL1 and VAL2. The first light emitting elements ED1 that have been aligned in the positive deflection during the first period t1 may be aligned in the positive deflection again, and the second light emitting elements ED2 that have been aligned in the negative deflection during the first period t1 may also be aligned in the positive deflection. Accordingly, the apparatus 1000 for manufacturing the display device may improve the alignment and deflection efficiency of the light emitting element ED, and may improve the luminous efficiency of the display device 10.

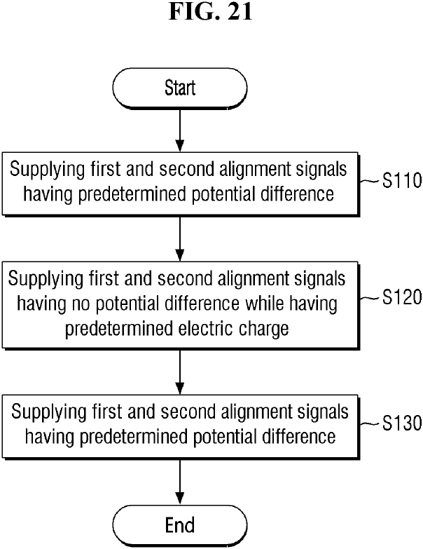

FIG. 21 is a schematic flowchart illustrating a manufacturing process of a display device according to an embodiment.

Referring to FIGS. 9 to 21, the electric field applying part 1500 may supply the first and second alignment signals AS1 and AS2 having a potential difference (e.g., a predetermined potential difference or selectable potential difference) to the first and second panel cells CEL1 and CEL2 during the first period t1 (step S110). The first vertical alignment line VAL1 may receive the first alignment signal AS1 through the first alignment pad AP1 during the first period t1, and the second vertical alignment line VAL2 may receive the second alignment signal AS2 through the second alignment pad AP2 during the first period t1. In case that the first and second alignment signals AS1 and AS2 have the potential difference (e.g., the predetermined potential difference or selectable potential difference), the electric field may be formed between the first and second vertical alignment lines VAL1 and VAL2. The first light emitting elements ED1 may be aligned in the positive deflection, and the second light emitting elements ED2 may be aligned in the negative deflection.

The electric field applying part 1500 may supply the first and second alignment signals AS1 and AS2 having no potential difference while having the electric charge (e.g., the predetermined electric charge or selectable electric charge) during the second period t2 after the first period t1 (step S120). The first vertical alignment line VAL1 may receive the first alignment signal AS1 through the first alignment pad AP1 during the second period t2, and the second vertical alignment line VAL2 may receive the second alignment signal AS2 through the second alignment pad AP2 during the second period t2. In case that the first and second alignment signals AS1 and AS2 do not have the potential difference, the electric field may be formed between the first and second vertical alignment lines VAL1 and VAL2. The first and second light emitting elements ED1 and ED2 may stand vertically by the electric field.

The electric field applying part 1500 may supply the first and second alignment signals AS1 and AS2 having the potential difference (e.g., the predetermined potential difference or selectable potential difference) during the third period t3 after the second period t2 (step S130). The first vertical alignment line VAL1 may receive the first alignment signal AS1 through the first alignment pad AP1 during the third period t3, and the second vertical alignment line VAL2 may receive the second alignment signal AS2 through the second alignment pad AP2 during the third period t3. In case that the first and second alignment signals AS1 and AS2 have the potential difference (e.g., the predetermined potential difference or selectable potential difference), the electric field may be formed between the first and second vertical alignment lines VAL1 and VAL2. The first light emitting elements ED1 that have been aligned in the positive deflection during the first period t1 may be aligned in the positive deflection again, and the second light emitting elements ED2 that have been aligned in the negative deflection during the first period t1 may also be aligned in the positive deflection. Accordingly, the apparatus 1000 for manufacturing the display device may improve the alignment and deflection efficiency of the light emitting element ED, and may improve the luminous efficiency of the display device 10.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. An apparatus for manufacturing a display device, comprising:
a panel cell disposed on a stage and comprising a first alignment line and a second alignment line extending in at least one direction;
an electric field applying part that supplies a first alignment signal and a second alignment signal to the panel cell; and
a light emitting element aligned between the first and second alignment lines,
wherein the electric field applying part supplies the first and second alignment signals having a potential difference to the first and second alignment lines, respectively, during a first period, and supplies the first and second alignment signals having a same potential to the first and second alignment lines, respectively, during a second period after the first period.

2. The apparatus of claim 1, wherein
the first alignment signal of the first period is an alternating current (AC) signal swinging with a frequency, and
the second alignment signal of the first period is a direct current (DC) signal having a voltage.

3. The apparatus of claim 1, wherein
the first and second alignment signals of the first period are AC signals swinging with a frequency, and
the first and second alignment signals have different phases from each other.

4. The apparatus of claim 1, wherein the first and second alignment signals of the second period are AC signals swinging with a same frequency and phase.

5. The apparatus of claim 4, wherein each of the first and second alignment signals of the second period is one of a sine wave, a square wave, a triangle wave, a pulse wave, a sawtooth wave, a sawtooth composite wave, and a reverse sawtooth composite wave.

6. The apparatus of claim 1, wherein
a force by an induced dipole is smaller than a force by a permanent dipole around the first and second alignment lines during the second period, and
the light emitting element stands vertically by an electric field around the first and second alignment lines during the second period.

7. The apparatus of claim 1, wherein the electric field applying part supplies the first and second alignment signals having a potential difference to the first and second alignment lines, respectively, during a third period after the second period.

8. The apparatus of claim 7, wherein
the first alignment signal of the third period is an AC signal swinging with a frequency, and
the second alignment signal of the third period is a DC signal having a voltage.

9. The apparatus of claim 7, wherein
the first and second alignment signals of the third period are AC signals swinging with a frequency, and
the first and second alignment signals have different phases from each other.

10. The apparatus of claim 9, wherein each of the first and second alignment signals of the third period is one of a sine wave, a square wave, a triangle wave, a pulse wave, a sawtooth wave, a sawtooth composite wave, and a reverse sawtooth composite wave.

11. The apparatus of claim 1, further comprising:
a voltage output part that generates and outputs the first and second alignment signals;
an amplifier that amplifies the first and second alignment signals and supplies the amplified first and second alignment signals to the electric field applying part;
a controller that supplies a control signal for determining waveforms of the first and second alignment signals to the voltage output part;
an emission driver that receives an emission timing signal from the controller and outputs an emission driving signal; and
a light irradiation part that receives the emission driving signal from the emission driver and irradiates light to the panel cell.

12. A method for manufacturing a display device, comprising:
providing a panel cell comprising a first alignment line and a second alignment line extending in at least one direction;
supplying a first alignment signal and a second alignment signal having a potential difference to the first and second alignment lines, respectively, during a first period;
supplying a first alignment signal and a second alignment signal having a same potential to the first and second alignment lines, respectively, during a second period after the first period; and
supplying a first alignment signal and a second alignment signal having a potential difference to the first and second alignment lines, respectively, during a third period after the second period.

13. The method of claim 12, wherein
the first alignment signal of the first period is an AC signal swinging with a frequency, and
the second alignment signal of the first period is a DC signal having a voltage.

14. The method of claim 12, wherein
the first and second alignment signals of the first period are AC signals swinging with a frequency, and
the first and second alignment signals have different phases from each other.

15. The method of claim 14, wherein the first and second alignment signals of the second period are AC signals swinging with a same frequency and phase.

16. The method of claim 15, wherein each of the first and second alignment signals of the second period is one of a sine wave, a square wave, a triangle wave, a pulse wave, a sawtooth wave, a sawtooth composite wave, and a reverse sawtooth composite wave.

17. The method of claim 12, wherein the supplying of the first and second alignment signals during the second period comprises:
forming an electric field around the first and second alignment lines to vertically erect a light emitting element aligned between the first and second alignment lines.

18. The method of claim 12, wherein
the first alignment signal of the third period is an AC signal swinging with a frequency, and
the second alignment signal of the third period is a DC signal having a voltage.

19. The method of claim 18, wherein
the first and second alignment signals of the third period are AC signals swinging with a frequency, and
the first and second alignment signals have different phases from each other.

20. The method of claim 19, wherein each of the first and second alignment signals of the third period is one of a sine wave, a square wave, a triangle wave, a pulse wave, a sawtooth wave, a sawtooth composite wave, and a reverse sawtooth composite wave.
